(19) United States
(12) Patent Application Publication
(10) Pub. No.: US 2025/0391813 A1
(43) Pub. Date: Dec. 25, 2025

(54) SEMICONDUCTOR PACKAGE AND METHOD OF FABRICATING THE SAME

(71) Applicant: Samsung Electronics Co., Ltd., Suwon-si (KR)

(72) Inventors: Hyunsoo Chung, Suwon-si (KR); Kwang-Soo Kim, Suwon-si (KR)

(21) Appl. No.: 18/977,204

(22) Filed: Dec. 11, 2024

(30) Foreign Application Priority Data
Jun. 19, 2024 (KR) 10-2024-0079421

(51) Int. Cl. H01L 25/065; H01L 21/3105; H01L 21/56; H01L 21/683; H01L 23/00; H01L 25/18; H10B 80/00

(52) U.S. Cl. CPC H01L 25/0652; H01L 21/31055; H01L 21/565; H01L 21/568; H01L 21/6836; H01L 24/11; H01L 24/14; H01L 24/16; H01L 24/48; H01L 24/73; H01L 25/18; H01L 24/06; H01L 24/32; H01L 2224/06132; H01L 2224/1134; H01L 2224/1403; H01L 2224/14132; H01L 2224/16227; H01L 2224/32145; H01L 2224/48227; H01L 2224/73253; H01L 2224/73257; H01L 2224/73265; H01L 2225/0651; H01L 2225/06517; H01L 2225/06562; H01L 2924/1815; H10B 80/00

(57) ABSTRACT

A semiconductor package includes a substrate, a first semiconductor chip on the substrate, a chip stack on the substrate spaced apart from the first semiconductor chip and including second semiconductor chips, and a mold layer on the substrate at least partially enclosing the chip stack and the first semiconductor chip. The first semiconductor chip includes first pads on a bottom surface of the first semiconductor chip facing the substrate, and second pads on the bottom surface of the first semiconductor chip. Each of the second semiconductor chips includes a third pad on a bottom surface thereof facing the substrate. The second semiconductor chips may be electrically connected to the substrate through connection wires connecting the third pads to substrate pads in the substrate. A distance between adjacent ones of the first pads may be larger than a distance between adjacent ones of the second pads.

### CROSS-REFERENCE TO RELATED APPLICATIONS

This U.S. non-provisional patent application claims priority under 35 U.S.C. § 119 to Korean Patent Application No. 10-2024-0079421, filed on Jun. 19, 2024, in the Korean Intellectual Property Office, the entire contents of which are hereby incorporated by reference.

### FIELD

The present disclosure relates to a semiconductor package and a method of fabricating the same.

### BACKGROUND

With advances in the electronics industry, demand for high-performance, high-speed, and compact electronic components are increasing. To meet demand, packaging technologies of mounting a plurality of semiconductor chips in a single package are being developed.

A semiconductor package may be configured to facilitate the use of an integrated circuit chip as a component in an electronic product. In general, the semiconductor package may include a printed circuit board (PCB) and a semiconductor chip, which is mounted on the PCB and is electrically connected to the PCB by bonding wires or bumps. With development of the electronics industry, a semiconductor package technology is developing in various ways with the goal of miniaturization, weight reduction, and manufacturing cost reduction. For this, it may be necessary to develop packaging technologies of reducing a size and a weight of each component and of integrating a plurality of individual components in a single package.

A general stack-type package may have a structure including a plurality of stacked devices. For example, the stack-type package may include semiconductor chips, which are sequentially stacked on a printed circuit board (PCB). Connection pads may be formed on the semiconductor chips. By forming bonding wires connected to the connection pads, the semiconductor chips may be electrically connected to the printed circuit board.

### SUMMARY

An embodiment of the inventive concept provides a semiconductor package with improved electrical characteristics and a method of fabricating the same.

An embodiment of the inventive concept provides a semiconductor package with a reduced size.

An embodiment of the inventive concept provides a method of simplifying a process of fabricating a semiconductor package and a semiconductor package fabricated thereby.

According to an embodiment of the inventive concept, a semiconductor package may include a substrate, a first semiconductor chip on the substrate, the first semiconductor chip having a first region and a second region in contact with the first region, a chip stack on the substrate spaced apart from the first semiconductor chip and adjacent to the first region, the chip stack including second semiconductor chips, which are stacked, and a mold layer on the substrate to at least partially enclosing the chip stack and the first semiconductor chip. The first semiconductor chip may comprise first pads in the first region on a bottom surface of the first semiconductor chip facing the substrate, and second pads in the second region on the bottom surface of the first semiconductor chip. Each of the second semiconductor chips may include a third pad on a bottom surface thereof facing the substrate, and the second semiconductor chips may be electrically connected to the substrate through connection wires connecting the third pads to substrate pads in the substrate. A distance between adjacent ones of the first pads may be larger than a distance between adjacent ones of the second pads.

According to an embodiment of the inventive concept, a semiconductor package may include a substrate, a first semiconductor chip on the substrate, a second semiconductor chip on the substrate spaced apart from the first semiconductor chip, wherein a side surface of the second semiconductor chip faces a first side surface of the first semiconductor chip, a connection wire extending from a bottom surface of the second semiconductor chip that faces the substrate, and a mold layer on the substrate to at least partially cover the first semiconductor chip and the second semiconductor chip. One end of the connection wire may be coupled to a first pad on the bottom surface of the second semiconductor chip, and an opposite end of the connection wire may be coupled to a substrate pad in the substrate. The opposite end of the connection wire may be closer to the first side surface than the one end of the connection wire, when viewed in a plan view.

According to an embodiment of the inventive concept, a method of fabricating a semiconductor package may include providing a first semiconductor chip on a carrier substrate, the first semiconductor chip including first pads on a top surface of the first semiconductor chip opposite the carrier substrate and connection bumps provided on some of the first pads, forming conductive balls on others of the first pads, stacking second semiconductor chips spaced apart from the first semiconductor chip on the carrier substrate to form a chip stack, forming first connection wires connecting the conductive balls to second pads of the second semiconductor chips, the first connection wires respectively comprising a first portion connected to the conductive balls and a second portion connected to the second pads, forming a mold layer on the carrier substrate to at least partially surround the first semiconductor chip, the chip stack, and the first connection wires, performing a thinning process on the mold layer to remove the first portion of the first connection wires, thereby forming second connection wires, wherein the thinning process does not expose a top surface of the chip stack opposite the carrier substrate, and forming a substrate electrically connected to the second connection wires, the connection bumps, and the conductive balls, on the mold layer.

### BRIEF DESCRIPTION OF THE DRAWINGS

FIG. 1 is a sectional view illustrating a semiconductor package according to an embodiment of the inventive concept.

FIG. 2 is an enlarged sectional view illustrating a portion (e.g., ‘P1’ of FIG. 1) of a semiconductor package according to an embodiment of the inventive concept.

FIGS. 3, 4, and 5 are sectional views illustrating a semiconductor package according to an embodiment of the inventive concept.

FIGS. 6, 7, 8, and 9 are sectional views illustrating a method of fabricating a semiconductor package, according to an embodiment of the inventive concept.

### DETAILED DESCRIPTION

Example embodiments of the inventive concepts will now be described more fully with reference to the accompanying drawings, in which example embodiments are shown.

It will be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings. except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

As used herein, active terms such as ‘burying’, ‘enclosing’, ‘covering’, ‘surrounding’, or ‘filling’ may not require completely burying, enclosing, covering, surrounding, or filing the described elements or layers, but may, for example, refer to partially burying, enclosing, covering, surrounding, or filling the described elements or layers, for example, with voids or other discontinuities throughout.

The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

The term “exposed” may be used to describe relationships between elements and/or certain intermediate processes in fabricating a completed semiconductor device but may not necessarily require exposure of the particular region, layer, structure or other element in the context of the completed device. Components or layers described with reference to “overlap” in a particular direction may be at least partially obstructed by one another when viewed along a line extending in the particular direction or in a plane perpendicular to the particular direction.

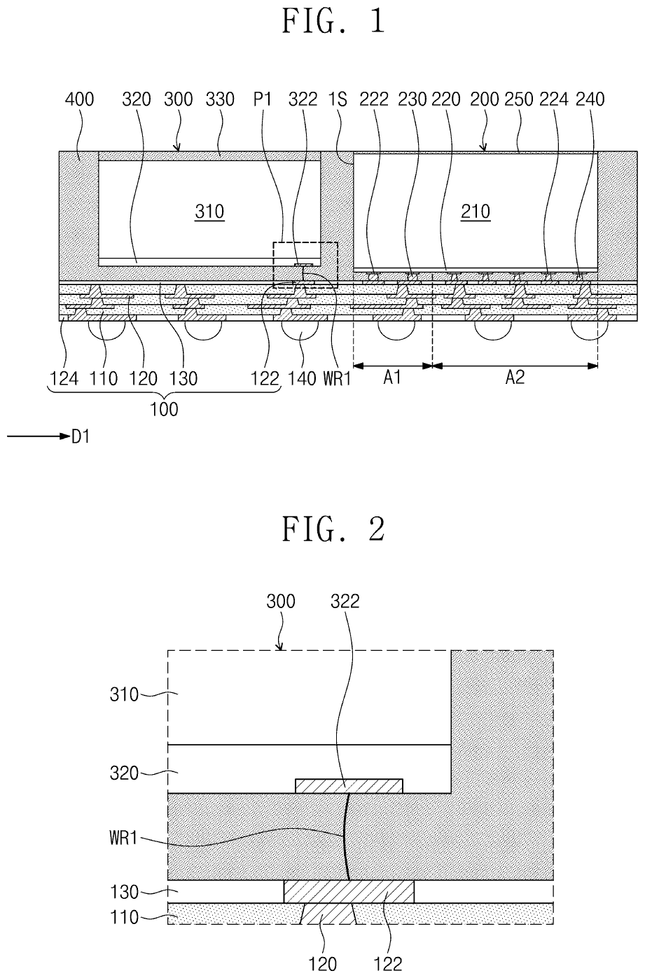

FIG. 1 is a sectional view illustrating a semiconductor package according to an embodiment of the inventive concept. FIG. 2 is an enlarged sectional view illustrating a portion (e.g., ‘P1’ of FIG. 1) of a semiconductor package according to an embodiment of the inventive concept.

Referring to FIGS. 1 and 2, a substrate 100 may be provided. The substrate 100 may be a redistribution substrate. For example, the substrate 100 may include two or more substrate interconnection layers which are sequentially stacked. In the present specification, the substrate interconnection layer may mean an interconnection layer, which includes a patterned structure of a single insulating layer and a patterned structure of a single conductive layer. That is, conductive patterns in each substrate interconnection layer may be horizontally-extended interconnection patterns that are not vertically overlapped with each other. Each of the substrate interconnection layer may include first insulating patterns 110 and first conductive patterns 120 in the first insulating patterns 110. The first conductive patterns 120 in one of the substrate interconnection layers may be electrically connected to the first conductive patterns 120 in a neighboring one of the substrate interconnection layers.

The first insulating patterns 110 may be formed of or include at least one of inorganic insulating materials (e.g., silicon oxide (SiO) or silicon nitride (SiN)). Alternatively, the first insulating patterns 110 may be formed of or include a polymer material. The first insulating patterns 110 may include an insulating polymer or a photoimageable polymer (e.g., photoimageable dielectric (PID) materials). For example, the PID materials may include at least one of photoimageable polyimides, polybenzoxazole (PBO), phenol-based polymers, and benzocyclobutene-based polymers.

The first conductive patterns 120 may be provided in the first insulating patterns 110. The first conductive patterns 120 may have a damascene structure. For example, the first conductive patterns 120 may include a head portion and a tail portion, which are connected to form a single object. The head portion may be a wire or pad portion, which is used to extend a wire in the substrate 100 in a horizontal direction. The tail portion may be a via portion, which is used to connect wires in the substrate 100 to each other in a vertical direction. The first conductive patterns 120 may have an inverted ‘T’ shaped section. In each of the substrate interconnection layers, the tail portion of the first conductive pattern 120 may be extended from a top surface of the head portion to penetrate the first insulating pattern 110 of another substrate interconnection layer thereon and may be coupled to the head portion of another of the first conductive patterns 120. In other words, a lower portion of the first conductive pattern 120, which is placed below the first insulating pattern 110, may be the head portion, which is used as a horizontal wire or a pad, and the tail portion of the first conductive pattern 120 may be the via portion. A top surface of the tail portion of the uppermost one of the first conductive patterns 120 may be exposed to a region on a top surface of the first insulating pattern 110 in the uppermost one of the substrate interconnection layers. The first conductive patterns 120 may include a conductive material. For example, the first conductive patterns 120 may include copper (Cu).

Upper substrate pads 122 may be disposed on the uppermost one of the substrate interconnection layers. For example, as shown in FIG. 1, in the uppermost one of the substrate interconnection layers, the tail portion of the first conductive patterns 120 may be exposed to a region on the top surface of the first insulating pattern 110, and the upper substrate pads 122 may be coupled to the exposed tail portion of the first conductive patterns 120. That is, the upper substrate pads 122 may protrude to a region on the top surface of the uppermost one of the first insulating patterns 110. The upper substrate pads 122 may be pads which are used to mount a first semiconductor chip 200 and a chip stack CS.

The substrate 100 may further include an upper substrate protection layer 130 protecting the substrate interconnection layers. The upper substrate protection layer 130 may be disposed on the uppermost one of the first insulating patterns 110. The upper substrate protection layer 130 may cover the uppermost one of the first insulating patterns 110 and may enclose the upper substrate pads 122. The upper substrate protection layer 130 may be provided to expose top surfaces of the upper substrate pads 122. A top surface of the upper substrate protection layer 130 may be coplanar with the top surfaces of the upper substrate pads 122. The upper substrate protection layer 130 may include an inorganic insulating material (e.g., silicon oxide (SiO) or silicon nitride (SiN)). Alternatively, the upper substrate protection layer 130 may include a polymer material. The upper substrate protection layer 130 may include an insulating polymer or a photoimageable polymer (e.g., photoimageable dielectric (PID) materials). For example, the PID materials may include photoimageable polyimides, polybenzoxazole (PBO), phenol-based polymers, or benzocyclobutene-based polymers.

FIG. 1 illustrates an example, in which the tail portions of the first conductive patterns 120 protrude to a region on the head portion, but the inventive concept is not limited to this example. The first conductive patterns 120 may be a ‘T’ shaped structure, in which the tail portion is connected to the bottom surface of the first conductive pattern 120. For example, a top surface of the head portion of the first conductive pattern 120 may be exposed to a region on the top surface of the first insulating pattern 110, and the tail portion of the first conductive pattern 120 may be exposed to a region on a bottom surface of the first insulating pattern 110. Here, the tail portion may be coupled to the head portion of the first conductive pattern 120 of the substrate interconnection layer thereunder.

Although not shown, a barrier layer may be interposed between the first insulating pattern 110 and the first conductive pattern 120. The barrier layer may conformally cover side and bottom surfaces of the first conductive pattern 120. The barrier layer may be formed of or include metallic materials (e.g., titanium (Ti) and tantalum (Ta)) or metal nitride materials (e.g., titanium nitride (TiN) and tantalum nitride (TaN)).

Lower substrate pads may be disposed on the bottom surface of the first insulating pattern 110, which is placed in the lowermost one of the substrate interconnection layers. The lower substrate pads may be portions of the first conductive patterns 120, which are extended to a region under a bottom surface of the substrate 100, or additional pads, which are placed below the lowermost one of the first insulating patterns 110 and are connected to the first conductive patterns 120. A lower substrate protection layer 124 may be disposed on the bottom surface of the substrate 100. The lower substrate protection layer 124 may cover the bottom surface of the substrate 100 and may expose the lower substrate pads. The lower substrate protection layer 124 may be formed of or include at least one of insulating polymers (e.g., epoxy-based polymer), an Ajinomoto build-up film (ABF), organic materials, or inorganic materials.

Outer terminals 140 may be provided below the substrate 100. Each of the outer terminals 140 may be disposed on a bottom surface of a corresponding one of the lower substrate pads. The outer terminals 140 may be electrically connected to the substrate 100 through the lower substrate pads. The outer terminals 140 may include solder balls or solder bumps.

The first semiconductor chip 200 may be disposed on the substrate 100. The first semiconductor chip 200 may be disposed on a top surface of the substrate 100. The first semiconductor chip 200 may be disposed on the substrate 100 in a face down manner. For example, the first semiconductor chip 200 may have a front surface facing the substrate 100 and a rear surface opposite to the front surface. Hereinafter, in the present specification, the front surface may be a surface of a semiconductor chip, on which integrated device and semiconductor chip pads are formed, and the rear surface may be another surface of the semiconductor chip that is opposite to the front surface. In FIG. 1, a bottom surface of the first semiconductor chip 200 may be the front surface of the first semiconductor chip 200.

The first semiconductor chip 200 may include a first semiconductor substrate 210. The first semiconductor substrate 210 may include a semiconductor material. For example, the first semiconductor substrate 210 may include silicon (Si). Although not shown, an integrated device or integrated circuits may be formed on a bottom surface of the first semiconductor substrate 210. The integrated device or the integrated circuits may include a logic circuit or a memory circuit. That is, the first semiconductor chip 200 may be a logic chip or a memory chip.

A first interconnection layer 220 may be provided on the bottom surface of the first semiconductor substrate 210. Although not shown, the first interconnection layer 220 may include a first chip insulating pattern and a first chip interconnection pattern, which is provided in the first chip insulating pattern. The first chip insulating pattern may be provided on the bottom surface of the first semiconductor substrate 210 to cover the integrated device or the integrated circuits. The first chip interconnection pattern may be coupled to the integrated device or the integrated circuits formed on the first semiconductor substrate 210.

The first semiconductor chip 200 may include a first region A1 and a second region A2. The first region A1 of the first semiconductor chip 200 may be a region, on which first pads 222 will be provided. The second region A2 of the first semiconductor chip 200 may be a region, on which second pads 224 will be provided, and may be a remaining region of the first semiconductor chip 200, excluding the first region A1. The first region A1 and the second region A2 may be in contact with each other. The first region A1 may be a region that is adjacent to a first side surface 1S of the first semiconductor chip 200. The second region A2 may be a region that is adjacent to a side surface of the first semiconductor chip 200 opposite to the first side surface 1S.

In the first region A1, the first pads 222 may be provided on the front surface of the first semiconductor chip 200. The first pads 222 may be laterally spaced apart from each other (e.g. in the direction D1), in the first region A1. The first pads 222 may be portions of the first chip interconnection pattern, which protrude from the first chip insulating pattern of the first interconnection layer 220, or additional pads, which are disposed on the first chip insulating pattern of the first interconnection layer 220 and are connected to the first chip interconnection patterns. However, the inventive concept is not limited to this example, and in an embodiment, the first pads 222 may be exposed from the first chip insulating pattern.

In the second region A2, the second pads 224 may be provided on the front surface of the first semiconductor chip 200. The second pads 224 may be laterally spaced apart from each other in the direction D1, in the second region A2. The second pads 224 may be portions of the first chip interconnection pattern, which protrude from the first chip insulating pattern of the first interconnection layer 220, or additional pads, which are disposed on the first chip insulating pattern of the first interconnection layer 220 and are connected to the first chip interconnection patterns. However, the inventive concept is not limited to this example, and in an embodiment, the second pads 224 may be exposed from the first chip insulating pattern.

A distance (e.g. in the direction D1) between two adjacent ones of the second pads 224 may be smaller than a distance between two adjacent ones of the first pads 222. The first and second pads 222 and 224 may be formed of or include at least one of conductive materials (e.g., metallic materials). For example, the first and second pads 222 and 224 may include copper (Cu). In an embodiment, the first pads 222 and the second pads 224 may be formed of the same material. The first pads 222 may be closer to the first side surface 1S than the second pads 224. The second pads 224 may be closer to the side surface of the first semiconductor chip 200, which is opposite to the first side surface 1S, than the first pads 222.

The first semiconductor chip 200 may be mounted on the substrate 100. The front surface of the first semiconductor chip 200 may face the substrate 100. The first semiconductor chip 200 may be mounted on the substrate 100 through wire balls 230, also referred to herein as conductive balls, and metal posts 240. The wire balls 230 may be provided below the first pads 222 of the first semiconductor chip 200. The wire balls 230 may be electrically connected to the first conductive pattern 120 of the substrate 100. Respective ends of the wire balls 230 may be in contact with the upper substrate pads 122 of the substrate 100. Opposite ends of the wire balls 230 may be connected to the first pads 222 of the first semiconductor chip 200. That is, the substrate 100 and the first pads 222 of the first semiconductor chip 200 may be electrically connected to each other through the wire balls 230. The wire balls 230 may include a conductive material. For example, the wire balls 230 may include gold (Au), but the inventive concept is not limited to this example. A height of the wire balls 230 may range from about 10 μm to about 100 μm. A distance between two adjacent ones of the wire balls 230 may be about 100 μm to about 150 μm. However, the inventive concept is not limited to this example, and in an embodiment, the distance between the two adjacent ones of the wire balls 230 may vary.

Connection bumps may be provided below the second pads 224 of the first semiconductor chip 200. The connection bumps may be the metal posts 240. The metal posts 240 may be disposed between the substrate 100 and the first semiconductor chip 200. The metal posts 240 may be electrically connected to the first conductive pattern 120 of the substrate 100. Respective ends of the metal posts 240 may be in contact with the upper substrate pads 122 of the substrate 100. Opposite ends of the metal posts 240 may be connected to the second pads 224 of the first semiconductor chip 200. In other words, the substrate 100 and the second pads 224 of the first semiconductor chip 200 may be electrically connected to each other through the metal posts 240. The metal posts 240 may have a tapered shape in a specific direction. Alternatively, the metal posts 240 may have a structure having a uniform width in a vertical direction. The metal posts 240 may include a conductive material. The conductive material may be formed of or include at least one of copper (Cu), aluminum (Al), silver (Ag), tin (Sn), gold (Au), nickel (Ni), lead (Pb), titanium (Ti), or alloys thereof. A distance between two adjacent ones of the metal posts 240 may range from about 45 μm to about 100 μm. However, the inventive concept is not limited to this example, and in an embodiment, the distance between the two adjacent ones of the metal posts 240 may vary. The distance between the two adjacent ones of the metal posts 240 may be equal to or shorter than the distance between the two adjacent ones of the wire balls 230. For example, the distance between the two adjacent ones of the metal posts 240 may be about 0.3 times to about 0.7 times the distance between the two adjacent ones of the wire balls 230. A height of the metal posts 240 may be equal to a height of the wire balls 230. The one ends of the metal posts 240 may be placed at the same vertical level with respect to the substrate 100 as the one ends of the wire balls 230. Since the first semiconductor chip 200 is mounted on the substrate 100 by the wire balls 230 and the metal posts 240, the first semiconductor chip 200 may be spaced apart from the top surface of the substrate 100.

A first adhesive layer 250 may be provided on the rear surface of the first semiconductor chip 200. The first adhesive layer 250 may include a die attach film (DAF) or a non-conductive film (NCF). However, the inventive concept is not limited to this example, and in an embodiment, the first adhesive layer 250 may not be provided.

A second semiconductor chip 300 may be provided on the substrate 100. The second semiconductor chip 300 may be spaced apart from the first semiconductor chip 200 in a first direction D1. A side surface of the second semiconductor chip 300 may be disposed to be adjacent to the first region A1 of the first semiconductor chip 200. The side surface of the second semiconductor chip 300 may face the first side surface 1S of the first semiconductor chip 200. In the present specification, the first direction D1 may be a direction that is parallel to the top surface of the substrate 100 and is oriented from the side surface of the second semiconductor chip 300 toward the first side surface 1S of the first semiconductor chip 200.

The second semiconductor chip 300 may be disposed on the substrate 100 in a face down manner. For example, the second semiconductor chip 300 may have a front surface facing the substrate 100 and a rear surface opposite to the front surface. In FIG. 1, a bottom surface of the second semiconductor chip 300 may be the front surface of the second semiconductor chip 300. The second semiconductor chip 300 may include a second semiconductor substrate 310. The second semiconductor substrate 310 may include a semiconductor material. In an embodiment, the second semiconductor substrate 310 may be formed of or include silicon (Si). Although not shown, an integrated device or integrated circuits may be formed on the bottom surface of the second semiconductor substrate 310. The integrated device or the integrated circuits may include a logic circuit or a memory circuit. In other words, the second semiconductor chip 300 may be a logic chip or a memory chip.

A second interconnection layer 320 may be provided on the bottom surface of the second semiconductor substrate 310. Although not shown, the second interconnection layer 320 may have a second chip insulating pattern and a second chip interconnection pattern, which is provided in the second chip insulating pattern. The second chip insulating pattern on the front surface of the second semiconductor chip 300 may cover the integrated device or the integrated circuits. The second chip interconnection pattern may be coupled to the integrated device or the integrated circuits formed on the second semiconductor substrate 310.

Third pads 322 may be provided on the front surface of the second semiconductor chip 300. The third pads 322 may be spaced apart from each other, on the front surface of the second semiconductor chip 300. The third pads 322 may be portions of the second chip interconnection pattern, which are exposed from the second chip insulating pattern of the second interconnection layer 320, or additional pads, which are disposed on the second chip insulating pattern of the second interconnection layer 320 and are connected to the second chip interconnection pattern. However, the inventive concept is not limited to this example, and in an embodiment, the third pads 322 may protrude from the second chip insulating pattern. The third pads 322 may be electrically connected to the integrated circuit of the second semiconductor chip 300. The third pads 322 may be placed at positions corresponding to the upper substrate pads 122 of the substrate 100. For example, the third pads 322 may face the upper substrate pads 122. The third pads 322 may be vertically aligned to the upper substrate pads 122 or may be slightly offset from the upper substrate pads 122. For example, at least a portion of each of the third pads 322 may be vertically overlapped with at least a portion of a corresponding one of the upper substrate pads 122.

A second adhesive layer 330 may be provided on the rear surface of the second semiconductor chip 300. The second adhesive layer 330 may cover the rear surface of the second semiconductor chip 300. The second adhesive layer 330 may include a die attach film (DAF) or a non-conductive film (NCF). However, the inventive concept is not limited to this example, and in an embodiment, the second adhesive layer 330 may not be provided.

The second semiconductor chip 300 may be spaced apart from the substrate 100. For example, the second semiconductor chip 300 may be spaced apart from the top surface of the substrate 100. Thus, the third pads 322 may be spaced apart from the substrate 100. A first distance of the second semiconductor chip 300 from the top surface of the substrate 100 may be larger than a second distance of the first semiconductor chip 200 from the top surface of the substrate 100. The first distance may range from about 20 μm to about 100 μm.

The second semiconductor chip 300 may be mounted on the substrate 100. In other words, the second semiconductor chip 300 may be electrically connected to the substrate 100. The second semiconductor chip 300 may be mounted on the substrate 100 using first connection wires WR1. Hereinafter, the connection structure between the second semiconductor chip 300 and the substrate 100 will be described in more detail with reference to one of the first connection wires WR1, for convenience in description.

The first connection wire WR1 may be provided to vertically and directly connect the third pad 322 of the second semiconductor chip 300 to the upper substrate pad 122 of the substrate 100. The first connection wire WR1 may be extended from a bottom surface of the third pad 322 to the top surface of the upper substrate pad 122, and the entirety of the first connection wire WR1 may be placed between the front surface of the second semiconductor chip 300 and the top surface of the substrate 100. One end of the first connection wire WR1 may be in contact with the bottom surface of the third pad 322. An opposite end of the first connection wire WR1 may be in contact with the top surface of the upper substrate pad 122 of the substrate 100. The first connection wire WR1 may be vertically extended from the bottom surface of the third pad 322. In other words, when viewed in a plan view, at least a portion of the opposite end of the first connection wire WR1 may be overlapped with the one end of the first connection wire WR1. However, the inventive concept is not limited to this example, and in an embodiment, on the top surface of the upper substrate pad 122, the opposite end of the first connection wire WR1 may be closer to the first side surface 1S than the one end of the first connection wire WR1. For example, when viewed in a plan view, the opposite end of the first connection wire WR1 may be spaced apart from the one end of the first connection wire WR1 in the first direction D1. An angle of the first connection wire WR1 to the bottom surface of the third pad 322 may range from about 30° to about 90°. The material of the first connection wire WR1 may be the same as the material of the wire balls 230.

A first mold layer 400 may be provided on the substrate 100. The first mold layer 400 may bury the first semiconductor chip 200 and the second semiconductor chip 300, on the top surface of the substrate 100. The first mold layer 400 may be provided to enclose the first and second semiconductor chips 200 and 300 but expose the top surfaces of the first and second semiconductor chips 200 and 300. The top surface of the first mold layer 400 may be coplanar with the top surface of the first semiconductor chip 200 and the top surface of the second semiconductor chip 300. In this case, the top surface of the first semiconductor chip 200 and the top surface of the second semiconductor chip 300 may refer to a top surface of the first adhesive layer 250 and a top surface of the second adhesive layer 330, respectively. The first mold layer 400 may fill spaces between the substrate 100 and the second semiconductor chip 300, between the second semiconductor chip 300 and the first semiconductor chip 200, and between the substrate 100 and the first semiconductor chip 200. The first mold layer 400 may be provided to fill a space between the front surface of the first semiconductor chip 200 and the top surface of the substrate 100 and to enclose the wire balls 230 and the metal posts 240. The first mold layer 400 may be provided to fill a space between the front surface of the second semiconductor chip 300 and the top surface of the substrate 100 and to enclose the first connection wires WR1 on the front surface of the second semiconductor chip 300. The second semiconductor chip 300 may be spaced apart from the substrate 100, with the first mold layer 400 interposed therebetween.

According to an embodiment of the inventive concept, the first connection wire WR1, which is used to mount the second semiconductor chip 300, may be vertically extended from the front surface of the second semiconductor chip 300 toward the substrate 100, rather than from the rear surface of the second semiconductor chip 300 toward the top surface of the substrate 100. This may make it possible to reduce the length of the first connection wire WR1 and to improve the electrical characteristics of the semiconductor package. In addition, the first connection wire WR1 may have a very small diameter or thickness, and this may make it possible to increase the integration density of the semiconductor package.

FIGS. 1 and 2 illustrate an example, in which the first semiconductor chip 200 and the second semiconductor chip 300 are provided on the substrate 100, but the inventive concept is not limited to this example.

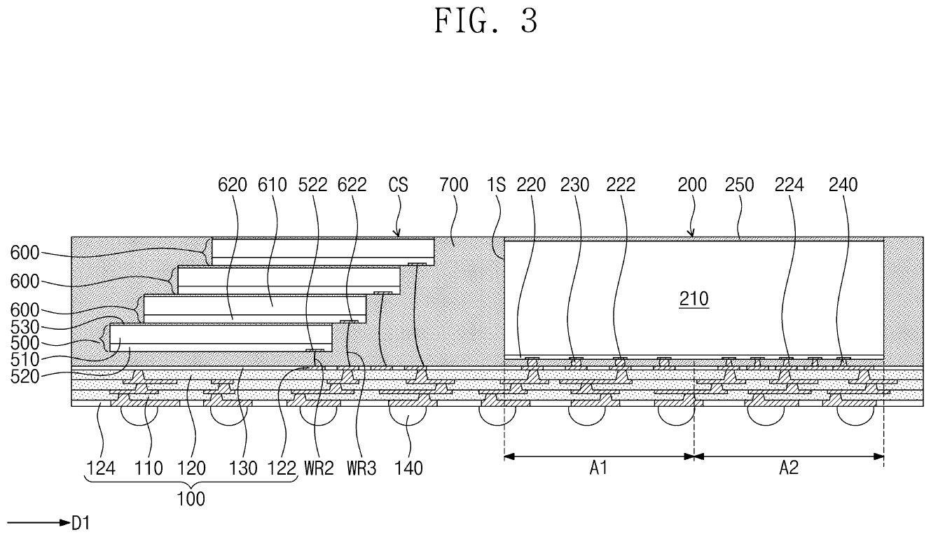

Referring to FIG. 3, the first semiconductor chip 200 and the chip stack CS may be provided on the substrate 100. Here, the first semiconductor chip 200 may be substantially the same as or similar to the first semiconductor chip 200 of FIG. 1. The chip stack CS may be spaced apart from the first semiconductor chip 200 in the first direction D1. The chip stack CS may include a plurality of semiconductor chips 500 and 600, which are sequentially stacked. The lowermost one of the semiconductor chips of the chip stack CS may be referred to as a third semiconductor chip 500, and the semiconductor chips stacked on the third semiconductor chip 500 may be referred to as fourth semiconductor chips 600. In the present specification, the term “third semiconductor chip 500” will be used to refer to the lowermost semiconductor chip in the chip stack CS, for convenience in description, and this means that the third and fourth semiconductor chips 500 and 600 may be of the same kind, even though they are referred to by different names. The third and fourth semiconductor chips 500 and 600 may be of the same kind or of different kinds. For example, each of the third and fourth semiconductor chips 500 and 600 may be a memory chip (e.g., DRAM, SRAM, MRAM, or FLASH memory chip). Alternatively, the third semiconductor chip 500 may be a logic chip, and the fourth semiconductor chips 600 may be memory chips. FIG. 3 illustrates the chip stack CS, which includes three fourth semiconductor chips 600, but the inventive concept is not limited to this example. The number of the semiconductor chips 500 and 600 in the chip stack CS may vary. For example, the chip stack CS may include one, two, or four or more fourth semiconductor chips 600.

The third semiconductor chip 500 may be disposed on the substrate 100 in a face down manner. For example, the third semiconductor chip 500 may have a front surface facing the substrate 100 and a rear surface opposite to the front surface. In FIG. 3, a bottom surface of the third semiconductor chip 500 may be the front surface of the third semiconductor chip 500. The third semiconductor chip 500 may include a third semiconductor substrate 510. The third semiconductor substrate 510 may include a semiconductor material. As an example, the third semiconductor substrate 510 may include silicon (Si). Although not shown, an integrated device or integrated circuits may be formed on a bottom surface of the third semiconductor substrate 510.

A third interconnection layer 520 may be provided on the bottom surface of the third semiconductor substrate 510. Although not shown, the third interconnection layer 520 may include a third chip insulating pattern and a third chip interconnection pattern provided in the third chip insulating pattern. The third chip insulating pattern may cover the integrated device or the integrated circuits, on the front surface of the third semiconductor chip 500. The third chip interconnection pattern may be coupled to the integrated device or the integrated circuits formed on the third semiconductor substrate 510.

Fourth pads 522 may be provided on the front surface of the third semiconductor chip 500. The fourth pads 522 may be spaced apart from each other, on the front surface of the third semiconductor chip 500. The fourth pads 522 may be portions of the third chip interconnection pattern, which are exposed from the third chip insulating pattern of the third interconnection layer 520, or additional pads, which are provided on the third chip insulating pattern of the third interconnection layer 520 and are connected to the third chip interconnection pattern. However, the inventive concept is not limited to this example, and in an embodiment, the fourth pads 522 may protrude from the third chip insulating pattern. The fourth pads 522 may be electrically connected to the integrated circuit of the third semiconductor chip 500.

The fourth semiconductor chips 600 may be disposed on the third semiconductor chip 500 in a face-down manner. For example, the fourth semiconductor chips 600 may have a front surface facing the substrate 100 and a rear surface opposite to the front surface. In FIG. 3, bottom surfaces of the fourth semiconductor chips 600 may be the front surface of the fourth semiconductor chips 600. Hereinafter, for convenience in description, the structure of the fourth semiconductor chips 600 will be described in more detail with reference to one of the fourth semiconductor chips 600.

The fourth semiconductor chip 600 may include a fourth semiconductor substrate 610. The fourth semiconductor substrate 610 may include a semiconductor material. As an example, the fourth semiconductor substrate 610 may include silicon (Si). Although not shown, an integrated device or integrated circuits may be formed on a bottom surface of the fourth semiconductor substrate 610. A fourth interconnection layer 620 may be provided on the bottom surface of the fourth semiconductor substrate 610. Although not shown, the fourth interconnection layer 620 may include a fourth chip insulating pattern and a fourth chip interconnection pattern provided in the fourth chip insulating pattern. The fourth chip insulating pattern may cover the integrated device or the integrated circuits, on the front surface of the fourth semiconductor chip 600. The fourth chip interconnection pattern may be coupled to the integrated device or the integrated circuits formed on the fourth semiconductor substrate 610.

Fifth pads 622 may be provided on the front surface of the fourth semiconductor chip 600. The fifth pads 622 may be spaced apart from each other, on the front surface of the fourth semiconductor chip 600. The fifth pads 622 may be portions of the fourth chip interconnection pattern, which are exposed from the fourth chip insulating pattern of the fourth interconnection layer 620, or additional pads, which are provided on the fourth chip insulating pattern of the fourth interconnection layer 620 and are connected to the fourth chip interconnection pattern. However, the inventive concept is not limited to this example, and in an embodiment, the fifth pads 622 may protrude from the fourth chip insulating pattern. The fifth pads 622 may be electrically connected to the integrated circuit of the fourth semiconductor chip 600.

A side surface of each of the third and fourth semiconductor chips 500 and 600 in the first direction D1 may be disposed to be adjacent to the first region A1 of the first semiconductor chip 200. The side surfaces of the third and fourth semiconductor chips 500 and 600 in the first direction D1 may face the first side surface 1S of the first semiconductor chip 200. The third and fourth semiconductor chips 500 and 600 may be disposed to form an offset stack structure. For example, the third and fourth semiconductor chips 500 and 600 may be stacked to be slanted in the first direction D1 parallel to the top surface of the substrate 100, thereby forming an upwardly inclined stepwise shape (i.e., a cascade shape). More specifically, each of the third and fourth semiconductor chips 500 and 600 may laterally protrude from another chip, which is placed therebelow, in the first direction D1.

Since the third and fourth semiconductor chips 500 and 600 are stacked in the stepwise or cascade shape, a portion of a front surface of each of the fourth semiconductor chips 600, which will be referred to as an exposed surface, may be exposed to the outside. According to an offset stacking direction of the third and fourth semiconductor chips 500 and 600, the exposed surfaces of the fourth semiconductor chips 600 may be adjacent to side surfaces of the fourth semiconductor chips 600 in the first direction D1. Here, the offset stacking direction may be defined as a direction in which each semiconductor chip is laterally shifted relative to an underlying semiconductor chip when the semiconductor chips are vertically stacked. In FIG. 3, the offset stacking direction of the third and fourth semiconductor chips 500 and 600 may be the first direction D1. The fourth pads 522 of the third semiconductor chip 500 may be provided on a front surface of the third semiconductor chip 500, and the fifth pads 622 of the fourth semiconductor chip 600 may be provided on the exposed surface of the front surface of the fourth semiconductor chip 600. The fourth and fifth pads 522 and 622 may be located at positions corresponding to the upper substrate pads 122 of the substrate 100. For example, the fourth and fifth pads 522 and 622 may face the upper substrate pads 122. The fourth and fifth pads 522 and 622 may be vertically aligned to the upper substrate pads 122 or may be slightly offset from the upper substrate pads 122. For example, at least a portion of each of the fourth and fifth pads 522 and 622 may be vertically overlapped with at least a portion of a corresponding one of the upper substrate pads 122.

Third adhesive layers 530 may be respectively provided on a rear surface of the third semiconductor chip 500 and rear surfaces of the fourth semiconductor chips 600. Each of the third and fourth semiconductor chips 500 and 600 may be attached to an underlying semiconductor chip using the third adhesive layer 530. In other words, each of the fourth semiconductor chips 600 may be attached to an underlying one of the fourth semiconductor chips 600 using the third adhesive layer 530, and the lowermost one of the fourth semiconductor chips 600 may be attached to the third semiconductor chip 500 using the third adhesive layer 530. The third adhesive layer 530 may be provided on the rear surface of the uppermost one of the fourth semiconductor chips 600, but in an embodiment, the third adhesive layer 530 may not be provided. The third adhesive layers 530 may include a die attach film (DAF) or a non-conductive film (NCF), but the inventive concept is not limited to this example.

The chip stack CS may be spaced apart from the substrate 100. For example, the third semiconductor chip 500 may be spaced apart from the top surface of the substrate 100. Thus, the fourth and fifth pads 522 and 622 may be spaced apart from the substrate 100. For example, a distance from the front surface of the third semiconductor chip 500 (i.e., the bottom surface of the third semiconductor chip 500) to the top surface of the substrate 100 may range from about 20 μm to about 100 μm, but the inventive concept is not limited to this example.

The chip stack CS may be mounted on the substrate 100. The third and fourth semiconductor chips 500 and 600 may be electrically connected to the substrate 100 using connection wires WR2 and WR3. In detail, the connection wires WR2 and WR3 may include second connection wires WR2, which are used to directly connect the fourth pads 522 of the third semiconductor chip 500 to the upper substrate pads 122 of the substrate 100, and third connection wires WR3, which are used to directly connect the fifth pads 622 of the fourth semiconductor chips 600 to the upper substrate pads 122 of the substrate 100.

The second connection wires WR2 may be extended from bottom surfaces of the fourth pads 522 to top surfaces of the upper substrate pads 122, and the entirety of the second connection wires WR2 may be placed between the bottom surface of the third semiconductor chip 500 and the top surface of the substrate 100. The second connection wires WR2 may be provided to vertically and directly connect the fourth pads 522 of the third semiconductor chip 500 to the upper substrate pads 122 of the substrate 100, respectively. One end of the second connection wires WR2 may be in contact with the bottom surfaces of the fourth pads 522. An opposite end of the second connection wires WR2 may be in contact with the top surfaces of the upper substrate pads 122 of the substrate 100. The second connection wires WR2 may be vertically extended from the bottom surfaces of the fourth pads 522. In other words, at least a portion of the opposite end of each of the second connection wires WR2 may be overlapped with the one end of each of the second connection wires WR2, when viewed in a plan view. However, the inventive concept is not limited to this example, and in an embodiment, on the top surface of the upper substrate pad 122, the opposite end of the second connection wire WR2 may be closer to the first side surface 1S than the one end of the second connection wire WR2. For example, when viewed in a plan view, the opposite end of the second connection wire WR2 may be spaced apart from the one end of the second connection wire WR2 in the first direction D1. An angle of the second connection wires WR2 to the bottom surface of the fourth pads 522 may range from about 30° to about 90°.

The third connection wires WR3 may be provided to vertically and directly connect the fifth pads 622 of the fourth semiconductor chips 600 to the upper substrate pads 122 of the substrate 100, respectively. The third connection wires WR3 may be extended from bottom surfaces of the fifth pads 622 to the top surfaces of the upper substrate pads 122, and the entirety of the third connection wires WR3 may be placed between the bottom surfaces of the fourth semiconductor chips 600 and the top surface of the substrate 100. One ends of the third connection wires WR3 may be in contact with the bottom surfaces of the fifth pads 622. Opposite ends of the third connection wires WR3 may be in contact with the top surfaces of the upper substrate pads 122 of the substrate 100. The third connection wires WR3 may be vertically extended from the bottom surfaces of the fifth pads 622. In other words, at least a portion of the opposite end of each of the third connection wires WR3 may be overlapped with the one end of each of the third connection wires WR3, when viewed in a plan view. However, the inventive concept is not limited to this example, and in an embodiment, on the top surfaces of the upper substrate pads 122, the opposite end of the third connection wire WR3 may be closer to the first side surface 1S than the one end of the third connection wire WR3. For example, when viewed in a plan view, the opposite end of the third connection wire WR3 may be spaced apart from the one end of the third connection wire WR3 in the first direction D1. An angle of the third connection wires WR3 to the bottom surfaces of the fifth pads 622 may range from about 30° to about 90°. The second and third connection wires WR2 and WR3 may be formed of or include a conductive material. The material of the second and third connection wires WR2 and WR3 may be the same as the material of the wire balls 230.

A second mold layer 700 may be provided on the substrate 100. The second mold layer 700 on the top surface of the substrate 100 may be provided to bury the chip stack CS and the first semiconductor chip 200. The second mold layer 700 may enclose the chip stack CS and may expose a top surface of the chip stack CS. The second mold layer 700 may enclose the first semiconductor chip 200 and may expose the top surface of the first semiconductor chip 200. The top surface of the second mold layer 700 may be coplanar with the top surface of the chip stack CS and the top surface of the first semiconductor chip 200. In this case, the top surface of the first semiconductor chip 200 and the top surface of the chip stack CS may refer to a top surface of a first adhesive layer 250 and a top surface of the third adhesive layer 530 at the uppermost portion of the chip stack, respectively. The second mold layer 700 may fill spaces between the substrate 100 and the chip stack CS, between the chip stack CS and the first semiconductor chip 200, and between the substrate 100 and the first semiconductor chip 200. The second mold layer 700 may fill a space between the bottom surface of the chip stack CS and the top surface of the substrate 100 and may be extended to a region below the bottom surface of the lowermost one of the third semiconductor chips 500 to enclose the second connection wires WR2. The second mold layer 700 may be provided to fill a space between the bottom surface of the first semiconductor chip 200 and the top surface of the substrate 100 and to enclose the wire balls 230 and the metal posts 240. The first semiconductor chip 200 and the chip stack CS may be spaced apart from the substrate 100 with the second mold layer 700 interposed therebetween.

FIG. 3 illustrates an example, in which one chip stack CS is mounted on the substrate 100, but the inventive concept is not limited to this example.

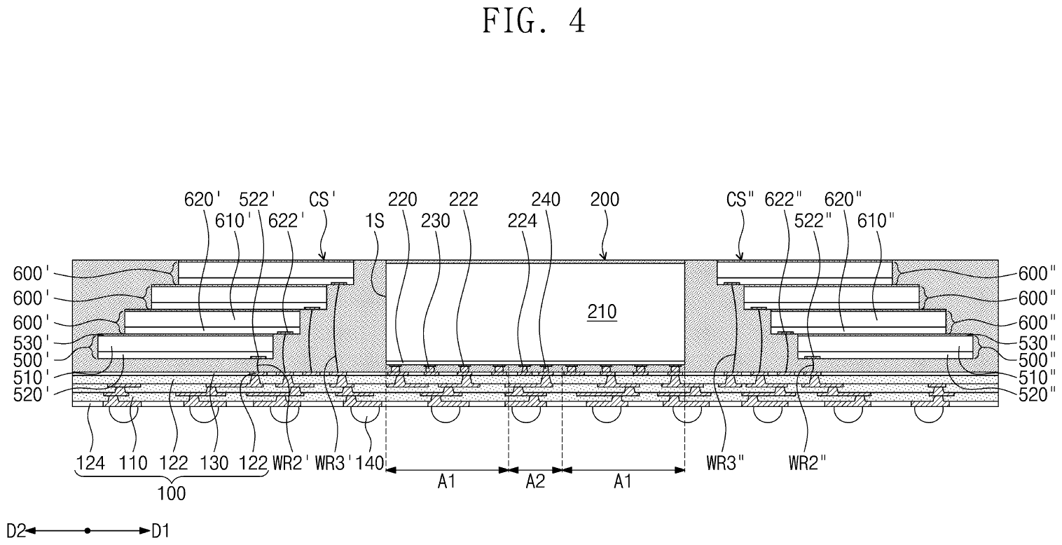

Referring to FIG. 4, chip stacks CS′ and CS″ may be provided on the substrate 100. The chip stacks CS′ and CS″ may be provided at both sides of the first semiconductor chip 200 to be spaced apart from each other. For example, the chip stacks CS′ and CS″ may be spaced apart from the first semiconductor chip 200 in the first direction D1 and a second direction D2, respectively. In the present specification, the second direction D2 may be a direction that is parallel to the top surface of the substrate 100 and is opposite to the first direction D1. The placement and the number of the chip stacks may be variously changed, but the semiconductor package of FIG. 4 will be supposed to include the two chip stacks CS′ and CS″ that are spaced apart from each other with the first semiconductor chip 200 interposed therebetween. One of the chip stacks CS′ and CS″, which is adjacent to the first side surface 1S of the first semiconductor chip 200, will be referred to as the first chip stack CS', and another one of the chip stacks CS′ and CS″ will be referred to as the second chip stack CS″. Each of the first and second chip stacks CS′ and CS″ may be substantially the same as or similar to the chip stack CS described with reference to FIG. 3, although they are referred to as the first and second chip stacks CS′ and CS″.

The semiconductor package may have a symmetrical shape relative to a center of the first semiconductor chip 200. The placement of the first chip stack CS′ may be substantially the same as the placement of the chip stack CS described with reference to FIG. 3. For example, in the first chip stack CS′, the third and fourth semiconductor chips 500′ and 600′, which are parallel to the top surface of the substrate 100, may be stacked to be slanted in the first direction D1, as shown in FIG. 3. Exposed surfaces of the fourth semiconductor chips 600′ of the first chip stack CS′ may be disposed to be adjacent to the first side surface 1S of the first semiconductor chip 200.

The second chip stack CS″ may include third and fourth semiconductor chips 500″ and 600″, which are parallel to the top surface of the substrate 100 and are stacked to be slanted in the second direction D2. In other words, an offset stacking direction of the fourth semiconductor chips 600″ may be opposite to an offset stacking direction of the fourth semiconductor chips 600′ of the first chip stack CS'. Each of the fourth semiconductor chips 600″ may protrude from the third semiconductor chip 500″ or the fourth semiconductor chip 600″, which is placed therebelow, in the second direction D2. The third and fourth semiconductor chips 500″ and 600″ of the second chip stack CS″ may have side surfaces facing a second side surface of the first semiconductor chip 200 opposite to the first side surface 1S. According to an offset stacking direction of the fourth semiconductor chips 600″, each of the fourth semiconductor chips 600″ may include an exposed surface that is placed to be adjacent to the second side surface. The fifth pads 622″ of the fourth semiconductor chips 600″ may be provided on the exposed portions of the front surfaces of the fourth semiconductor chips 600″.

The fourth and fifth pads 522″ and 622″ may be located at positions corresponding to the upper substrate pads 122 of the substrate 100. Each of the fourth and fifth pads 522″ and 622″ may face a corresponding one of the upper substrate pads 122. The fourth and fifth pads 522″ and 622″ may be vertically aligned to the upper substrate pads 122 or may be slightly offset from the upper substrate pads 122. For example, at least a portion of each of the fourth and fifth pads 522″ and 622″ may be vertically overlapped with at least a portion of a corresponding one of the upper substrate pads 122.

The second chip stack CS″ may be mounted on the substrate 100 through second and third connection wires WR2″ and WR3″. The second connection wires WR2″ may be extended from a bottom surface of each of the fourth pads 522″ to a top surface of a corresponding one of the upper substrate pads 122. Each of the third connection wires WR3″ may be extended from the bottom surface of each of the fifth pads 622″ to a top surface of a corresponding one of the upper substrate pads 122. Hereinafter, the shapes and arrangement of the second and third connection wires WR2″ and WR3″ will be described with reference to one second connection wire WR2″ and one third connection wire WR3″.

The entirety of the second connection wire WR2″ may be placed between the front surface of the third semiconductor chip 500″ and the top surface of the substrate 100. One end of the second connection wire WR2″ may be in contact with the bottom surface of the fourth pad 522″. An opposite end of the second connection wire WR2″ may be in contact with the top surface of the upper substrate pad 122. When viewed in a plan view, the opposite end of the second connection wire WR2″ may be overlapped with the one end of the second connection wire WR2″. Alternatively, on the top surface of the upper substrate pad 122, the opposite end of the second connection wire WR2″ may be closer to the second side surface than the one end of the second connection wire WR2″. For example, when viewed in a plan view, the opposite end of the second connection wire WR2″ may be spaced apart from the one end of the second connection wire WR2″ in the second direction D2. An angle of the second connection wire WR2″ to the bottom surface of the fourth pad 522″ may range from about 30° to about 90°.

The entirety of the third connection wire WR3″ may be placed between the front surface of the fourth semiconductor chip 600″ and the top surface of the substrate 100. One end of the third connection wire WR3″ may be in contact with the bottom surface of the fifth pad 622″. An opposite end of the third connection wire WR3″ may be in contact with the top surface of the upper substrate pad 122. When viewed in a plan view, the opposite end of the third connection wire WR3″ may be overlapped with the one end of the third connection wire WR3″. Alternatively, on the top surface of the upper substrate pad 122, the opposite end of the third connection wire WR3″ may be closer to the second side surface than the one end of the third connection wire WR3″. For example, when viewed in a plan view, the opposite end of the third connection wire WR3″ may be spaced apart from the one end of the third connection wire WR3″ in the second direction D2. An angle of the third connection wire WR3″ to the bottom surface of the fifth pad 622″ may range from about 30° to about 90°.

The second and third connection wires WR2″ and WR3″ may be formed of the same material as the wire balls 230. The material of the second and third connection wires WR2′ and WR3′ of the first chip stack CS′ may be the same as the material of the second and third connection wires WR2″ and WR3″ of the second chip stack CS″.

The first semiconductor chip 200 may be provided between the chip stacks CS′ and CS″. Here, unlike the structures of FIGS. 1 to 3, the second region A2 of the first semiconductor chip 200 may be located at a center portion of the first semiconductor chip 200. In an embodiment, the first semiconductor chip 200 may include a plurality of the first regions A1. For example, the first regions A1 may be two regions. The first regions A1 may be in contact with opposite sides of the second region A2 and may be placed in a peripheral portion of the first semiconductor chip 200. Each of the first regions A1 may be in contact with the second region A2. One of the first regions A1 may be adjacent to the first side surface 1S of the first semiconductor chip 200. Another one of the first regions A1 may be adjacent to the second side surface. The first region A1 may be a region, on which the first pads 222 of the first semiconductor chip 200 are provided. The second region A2 may be a region, on which the second pads 224 of the first semiconductor chip 200 are provided.

The first pads 222 may be spaced apart from each other, in the first regions A1. The second pads 224 may be spaced apart from each other, in the second region A2. Since the first regions A1 are respectively placed at both sides of the second region A2, the second pads 224 may be disposed between the first pads 222. A distance between two adjacent ones of the second pads 224 may be smaller than a distance between two adjacent ones of the first pads 222. The wire balls 230 may be provided on bottom surfaces of the first pads 222. The metal posts 240 may be provided on bottom surfaces of the second pads 224. A distance between two adjacent ones of the metal posts 240 may be equal to or smaller than a distance between two adjacent ones of the wire balls 230. For example, the distance between the two adjacent ones of the metal posts 240 may be about 0.3 times to about 0.7 times of the distance between the two adjacent ones of the wire balls 230.

FIG. 3 illustrates an example, in which the third semiconductor chip 500 of the chip stack CS is mounted on the substrate 100 using the second connection wires WR2, but the inventive concept is not limited to this example.

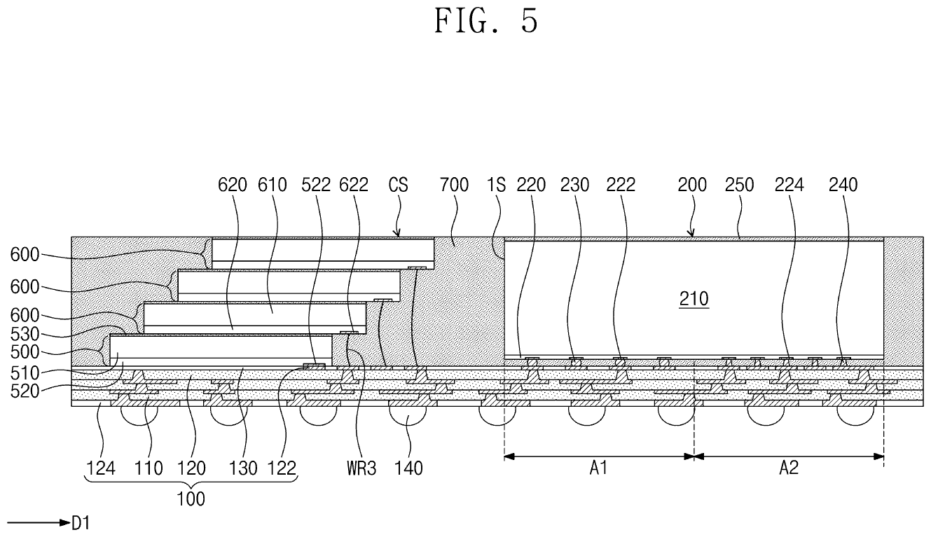

Referring to FIG. 5, the first semiconductor chip 200 and the chip stack CS may be mounted on the substrate 100. Here, the first semiconductor chip 200 and the chip stack CS may have substantially the same structure as that described with reference to FIG. 3. However, the second connection wire WR2 may not be provided on the front surface of the third semiconductor chip 500, unlike the structure of FIG. 3. The chip stack CS may not be spaced apart from the substrate 100. In detail, the bottom surface of the chip stack CS may be in contact with the substrate 100. The third semiconductor chip 500 may be in contact with the substrate 100. On an interface between the third semiconductor chip 500 and the substrate 100, the fourth pads 522 of the third semiconductor chip 500 may be in direct contact with the upper substrate pads 122 of the substrate 100, respectively. For example, the fourth pads 522 and the upper substrate pads 122 may form an inter-metal hybrid bonding structure. The fourth pads 522 and the upper substrate pads 122, which are bonded to each other, may have a continuous structure, and interfaces between the fourth pads 522 and the upper substrate pads 122 may not be visible. For example, the fourth pads 522 and the upper substrate pads 122 may be formed of the same material to serve as a single element. For example, the fourth pad 522 and the upper substrate pad 122 may be bonded to form a single object. Hereinafter, the bonding structure of the fourth pads 522 and the upper substrate pads 122 will be described in more detail with reference to one fourth pad 522 and one upper substrate pad 122.

A width of the fourth pad 522 may be equal to a width of the upper substrate pad 122. In FIG. 5, the fourth pad 522 is illustrated to have the same width as the upper substrate pad 122, but the inventive concept is not limited to this example. One of the fourth pad 522 and the upper substrate pad 122 may have a width larger than the other. Here, at least a portion of the fourth pad 522 may be vertically overlapped with at least a portion of the upper substrate pad 122. The fourth pad 522 may have the same planar shape as the upper substrate pad 122.

The fourth semiconductor chips 600 may be electrically connected to the substrate 100 through the third connection wires WR3. As shown in FIG. 3, the third connection wires WR3 may be provided to vertically and directly connect the fifth pads 622 of the fourth semiconductor chips 600 to the upper substrate pads 122 of the substrate 100, respectively. The third connection wires WR3 may be extended from bottom surfaces of the fifth pads 622 to top surfaces of the upper substrate pads 122, and the entirety of the third connection wires WR3 may be placed between the bottom surfaces of the fourth semiconductor chips 600 and the top surface of the substrate 100.

The top surface of the chip stack CS may be coplanar with the top surface of the first semiconductor chip 200. The second mold layer 700 may be provided on the top surface of the substrate 100 to enclose the chip stack CS and the first semiconductor chip 200. A top surface of the second mold layer 700 may be coplanar with the top surface of the chip stack CS and the top surface of the first semiconductor chip 200. In this case, the top surface of the first semiconductor chip 200 and the top surface of the chip stack CS may refer to a top surface of a first adhesive layer 250 and a top surface of the third adhesive layer 530 at the uppermost portion of the chip stack, respectively. The second mold layer 700 may fill a space between exposed surfaces of the fourth semiconductor chips 600 and the top surface of the substrate 100 and may enclose the third connection wires WR3.

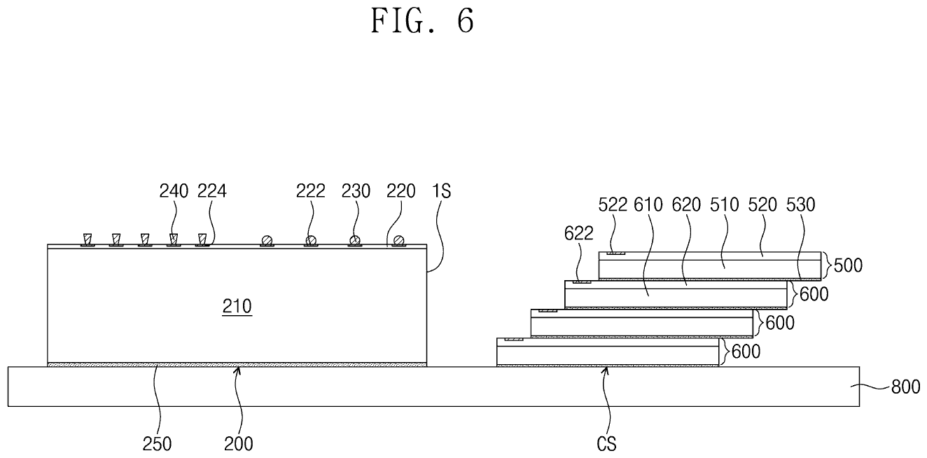

FIGS. 6 to 9 are sectional views illustrating a method of fabricating a semiconductor package, according to an embodiment of the inventive concept. Referring to FIG. 6, a carrier substrate 800 may be provided. The carrier substrate 800 may be an insulating substrate (e.g., including glass or polymer) or a conductive substrate (e.g., including a metallic material). Although not shown, an adhesive member may be provided on a top surface of the carrier substrate 800. As an example, the adhesive member may include an adhesive tape.

The first semiconductor chip 200 may be provided on the carrier substrate 800. The first semiconductor chip 200 may be attached to the carrier substrate 800 using the first adhesive layer 250. The first semiconductor chip 200 may be disposed in a face-up manner. For example, the first semiconductor chip 200 may be provided to have a rear surface facing the carrier substrate 800 and to include the first and second pads 222 and 224, which are opposite to the carrier substrate 800. The metal posts 240 may be formed on top surfaces of the second pads 224. The metal posts 240 may include a conductive material.

The wire balls 230 may be formed on top surfaces of the first pads 222. The wire balls 230 may be formed using a capillary. For example, the capillary may be placed on a top surface of one of the first pads 222. The capillary may be configured to melt a wire, which is injected into the same, and to form the wire ball 230 at a bottom end thereof. The wire ball 230 may be attached to one of the first pads 222. On the top surface of each of the first pads 222, the capillary may be moved to repeat the process of forming the wire ball 230. The wire balls 230 may be used as bumps for the physical bonding between one ends of the first and second connection wires WR1 and WR2 and the first pads 222.

The chip stack CS may be provided on the carrier substrate 800. The chip stack CS on the carrier substrate 800 may be spaced apart from the first semiconductor chip 200. The fourth semiconductor chips 600 may be disposed in such a way that the fifth pads 622 of the fourth semiconductor chips 600 are adjacent to the first side surface 1S of the first semiconductor chip 200. The third semiconductor chip 500 may be disposed on the uppermost one of the fourth semiconductor chips 600 such that the fourth pads 522 are adjacent to the first side surface 1S of the first semiconductor chip 200. The chip stack CS may be attached to the carrier substrate 800. The fourth semiconductor chip 600 may be attached to the carrier substrate 800 using the third adhesive layer 530, another fourth semiconductor chip 600 may be attached to the fourth semiconductor chip 600 using the third adhesive layer 530, and the third semiconductor chip 500 may be attached to the fourth semiconductor chips 600 stacked using the third adhesive layer 530. Alternatively, the lowermost one of the fourth semiconductor chips 600 may be attached to the carrier substrate 800 using the adhesive member, which is provided on the carrier substrate 800, without the third adhesive layer 530. The third and fourth semiconductor chips 500 and 600 may be disposed in a face-up manner. In other words, the third and fourth semiconductor chips 500 and 600 may be provided to have rear surfaces facing the carrier substrate 800 and to include the fourth and fifth pads 522 and 622, which are opposite to the carrier substrate 800. When the fourth semiconductor chips 600 are vertically stacked, the fourth semiconductor chips 600 may be shifted relative to each other in a direction, which is parallel to the top surface of the carrier substrate 800, to expose the fifth pads 622.

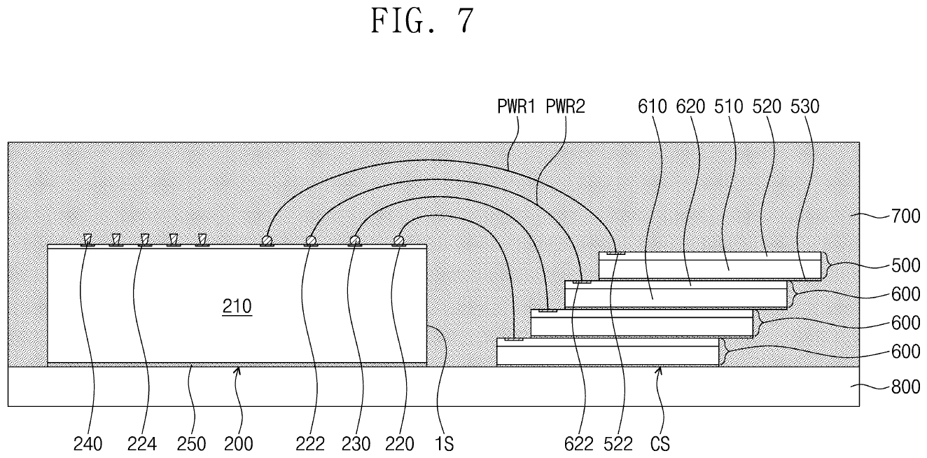

Referring to FIG. 7, the chip stack CS and the first semiconductor chip 200 may be bonded to each other using connection wires. For example, the third and fourth semiconductor chips 500 and 600 of the chip stack CS may be coupled to the wire balls 230 on the first pads 222. In detail, one ends of first preliminary connection wires PWR1 may be coupled to the fourth pads 522 of the third semiconductor chip 500. Opposite ends of the first preliminary connection wires PWR1 may be coupled to some of the wire balls 230. Each of the first preliminary connection wires PWR1 may connect each of the fourth pads 522 to a corresponding one of the wire balls 230. The uppermost portion of each of the first preliminary connection wires PWR1 may be located at a level higher than the top surface of the chip stack CS. One ends of second preliminary connection wires PWR2 may be coupled to the fifth pads 622 of the fourth semiconductor chips 600. Opposite ends of the second preliminary connection wires PWR2 may be coupled to remaining ones of the wire balls 230. Each of the second preliminary connection wires PWR2 may connect each of the fifth pads 622 to a corresponding one of the wire balls 230. The uppermost portion of each of the second preliminary connection wires PWR2 may be located at a level higher than the top surface of the chip stack CS. The first and second preliminary connection wires PWR1 and PWR2 may also be referred to as first connection wires.

The second mold layer 700 may be formed on the carrier substrate 800. For example, a molding material may be coated on the top surface of the carrier substrate 800 to bury the chip stack CS, the first semiconductor chip 200, and the preliminary connection wires PWR1 and PWR2, and then, the molding material may be cured to form the second mold layer 700. In an embodiment, the molding material may include an epoxy molding compound (EMC).

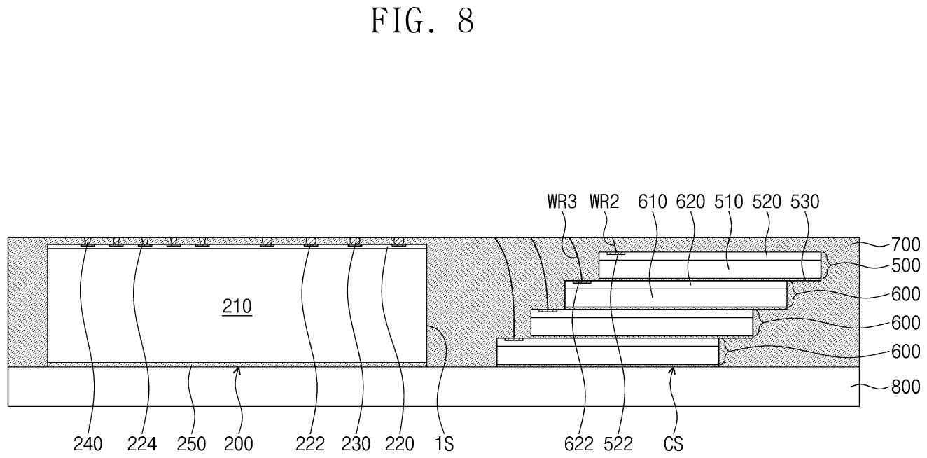

Referring to FIG. 8, a thinning process may be performed on the second mold layer 700. The thinning process may include a chemical machinal polishing (CMP) process or a grinding process. A top surface of the second mold layer 700 may be lowered by the thinning process. During the thinning process, the first preliminary connection wires PWR1 and the second preliminary connection wires PWR2 may be exposed to the outside. Upper portions of the exposed first and second preliminary connection wires PWR1 and PWR2 may be removed during the thinning process. In an embodiment, one ends of the first and second preliminary connection wires PWR1 and PWR2, which are connected to the wire balls 230, may be removed.

In other words, the first preliminary connection wires PWR1 may include a first portion connected to the wire balls 230 and a second portion connected to the fourth pads 522. The first portion may refer to the one ends of the first preliminary connection wires PWR1, which are coupled to the wire balls 230, and portions of the first preliminary connection wires PWR1, which are extended therefrom, and the second portion may refer to the remaining portions of the first preliminary connection wires PWR1, excluding the first portion. The first portions of the first preliminary connection wires PWR1 may be removed during the thinning process. The second preliminary connection wires PWR2 may include a third portion connected to the wire balls 230 and a fourth portion connected to the fifth pads 622. The third portion may refer to the one ends of the second preliminary connection wires PWR2, which are coupled to the wire balls 230, and portions of the second preliminary connection wires PWR2, which are extended therefrom, and the fourth portion may refer to the remaining portions of the second preliminary connection wires PWR2, excluding the third portion. The third portions of the second preliminary connection wires PWR2 may be removed, during the thinning process.

In an embodiment, upper portions of the wire balls 230, which are connected to the first portion and the third portion, may also be removed, when the first portions of the first preliminary connection wires PWR1 and the third portions of the second preliminary connection wires PWR2 are removed. Since the upper portions of the wire balls 230 removed, the wire balls 230 may be exposed to a region on the top surface of the second mold layer 700. An upper portion of the metal post 240 may be removed by the thinning process. Since the upper portion of the metal post 240 is removed, a top surface of the metal post 240 may be exposed to a region on the top surface of the second mold layer 700. The thinning process may be performed in such a way that the top surface of the chip stack CS is not exposed to the outside. That is, the chip stack CS may be buried in the second mold layer 700 and may not be exposed to a region on the top surface of the second mold layer 700.

Thus, the second connection wires WR2, which are coupled to the fourth pads 522, may be formed from the first preliminary connection wires PWR1, and the third connection wires WR3, which are coupled to the fifth pads 622, may be formed from the second preliminary connection wires PWR2. The second connection wires WR2 may be the second portions of the first preliminary connection wires PWR1. The third connection wires WR3 may be the fourth portions of the second preliminary connection wires PWR2. The second connection wires WR2 may be extended from the fourth pads 522 in an upward direction. One ends of the second connection wires WR2 may be exposed to a region on the top surface of the second mold layer 700. The third connection wires WR3 may be extended from the fifth pads 622 in an upward direction. One ends of the third connection wires WR3 may be exposed to a region on the top surface of the second mold layer 700. The second connection wires WR2 and third connection wires WR3 may also be referred to as second connection wires.

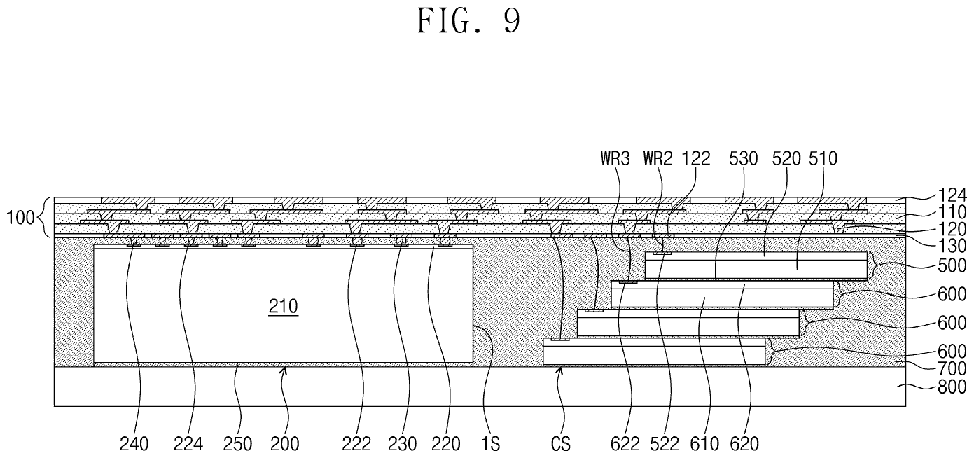

Referring to FIG. 9, the substrate 100 may be formed. Hereinafter, the formation of the substrate 100 will be described in more detail. The upper substrate protection layer 130 may be formed on the second mold layer 700. The upper substrate protection layer 130 may include an insulating polymer or a photoimageable polymer.

The upper substrate pads 122 may be formed in the upper substrate protection layer 130. For example, the upper substrate protection layer 130 may be patterned to form openings, in which the upper substrate pads 122 will be formed. The openings may be formed to expose the second and third connection wires WR2 and WR3. Thereafter, a seed layer may be conformally formed in the openings, and then, the upper substrate pads 122 filling the openings may be formed by a plating process using the seed layer as a seed. The upper substrate pads 122 may be coupled to the wire balls 230, the metal posts 240, and the second and third connection wires WR2 and WR3.

The first insulating pattern 110 may be formed on the upper substrate protection layer 130. The first insulating pattern 110 may be formed by a coating process (e.g., a spin coating process or a slit coating process). The first insulating pattern 110 may include a photoimageable polymers. In an embodiment, the photoimageable polymers may include photo-imageable polyimides, polybenzoxazole (PBO), phenol-based polymers, and benzocyclobutene-based polymers. Openings may be formed in the first insulating pattern 110. For example, the openings may be formed by patterning the first insulating pattern 110. The openings may be formed to expose the upper substrate pads 122.

The first conductive pattern 120 may be formed. For example, a barrier layer and a conductive layer may be formed on the first insulating pattern 110 to cover a top surface of the first insulating pattern 110 and to fill the openings, and then, the barrier layer and the conductive layer may be patterned to form the first conductive pattern 120. The first insulating pattern 110 and the first conductive pattern 120, which are formed by the above process, may form a single substrate interconnection layer. The substrate 100, which includes a plurality of substrate interconnection layers, may be formed by repeating the process of forming the first insulating pattern 110 and the first conductive pattern 120. A portion of a head portion of the first conductive pattern 120, which is located on the top surface of the first insulating pattern 110, may correspond to the lower substrate pads of the substrate 100.

Referring back to FIG. 3, the outer terminals 140 may be formed on bottom surfaces of the lower substrate pads. Next, the resulting structure may be inverted. The substrate 100 may be placed on bottom surfaces of the chip stack CS and the first semiconductor chip 200. The carrier substrate 800 may be removed to expose the top surfaces of the chip stack CS, the first semiconductor chip 200, and the second mold layer 700. As a result of the afore-described fabrication process, the semiconductor package may have the same structure as that of FIG. 3.

In a semiconductor package according to an embodiment of the inventive concept, a connection wire, which are used to mount chip stacks, may be vertically extended from a top surface of a semiconductor chips toward a redistribution layer. Thus, a small-sized semiconductor package may be provided.

In addition, since the connection wire is vertically extended from the top surface of the semiconductor chips toward the redistribution layer, the connection wire may have a reduced length, and the electrical characteristics of the semiconductor package may be improved.

In a method of fabricating a semiconductor package according to an embodiment of the inventive concept, a vertical connection terminal, which is used to connect chip stacks to a redistribution layer, may be formed by a relatively simple wiring process, and thus, it may be possible to simplify a process of fabricating a semiconductor package. In addition, it may be possible to reduce a fabrication cost in a process of fabricating a semiconductor package and to increase a degree of freedom in constructing a wiring structure.

While example embodiments of the inventive concept have been particularly shown and described, it will be understood by one of ordinary skill in the art that variations in form and detail may be made therein without departing from the scope of the attached claims.

What is claimed is:

1. A semiconductor package, comprising:
a substrate;
a first semiconductor chip on the substrate, the first semiconductor chip having a first region and a second region in contact with the first region;
a chip stack on the substrate spaced apart from the first semiconductor chip and adjacent to the first region, the chip stack comprising second semiconductor chips, which are stacked; and
a mold layer on the substrate at least partially enclosing the chip stack and the first semiconductor chip,
wherein the first semiconductor chip comprises:
first pads in the first region on a bottom surface of the first semiconductor chip facing the substrate; and
second pads in the second region on the bottom surface of the first semiconductor chip,
each of the second semiconductor chips comprises a third pad on a bottom surface thereof facing the substrate,
the second semiconductor chips are electrically connected to the substrate through connection wires connecting the third pads to substrate pads in the substrate, and
a distance between adjacent ones of the first pads is larger than a distance between adjacent ones of the second pads.

2. The semiconductor package of claim 1, wherein at least one of the first pads and at least one of the substrate pads are connected to each other through conductive balls that comprise a same material as the connection wires.

3. The semiconductor package of claim 2, wherein at least one of the second pads and at least one of the substrate pads are connected to each other through connection bumps, comprising metal posts at least partially penetrating the mold layer.

4. The semiconductor package of claim 3, wherein a distance between adjacent ones of the metal posts is about 0.3 times to about 0.7 times a distance between adjacent ones of the conductive balls.

5. The semiconductor package of claim 1, wherein a top surface of the mold layer is coplanar with a top surface of the chip stack and a top surface of the first semiconductor chip.

6. The semiconductor package of claim 1, wherein the connection wires are between the bottom surface of a respective one of the second semiconductor chips and the substrate, and
at least one of the connection wires directly connects at least one of the third pads to at least one of the substrate pads.

7. The semiconductor package of claim 1, wherein the second semiconductor chips extend parallel to a top surface of the substrate and are stacked to form a stepwise or cascade arrangement, and
each of the second semiconductor chips is arranged to at least partially expose the third pad of another of the second semiconductor chips thereon.

8. The semiconductor package of claim 1, wherein the chip stack and the first semiconductor chip are spaced apart from a top surface of the substrate,
wherein a first distance between a bottom surface of the chip stack that faces the substrate and the top surface of the substrate is larger than a second distance between the bottom surface of the first semiconductor chip and the top surface of the substrate, and
wherein the first distance is about 20 μm to about 100 μm.

9. The semiconductor package of claim 1, wherein each of the third pads is at least partially overlapped by at least a portion of a corresponding substrate pad among the substrate pads.

10. A semiconductor package, comprising:
a substrate;
a first semiconductor chip on the substrate;
a second semiconductor chip on the substrate spaced apart from the first semiconductor chip, wherein a side surface of the second semiconductor chip faces a first side surface of the first semiconductor chip;
a connection wire extending from a bottom surface of the second semiconductor chip that faces the substrate; and
a mold layer on the substrate to at least partially cover the first semiconductor chip and the second semiconductor chip,
wherein one end of the connection wire is coupled to a first pad on the bottom surface of the second semiconductor chip,
wherein an opposite end of the connection wire is coupled to a substrate pad in the substrate, and
wherein the opposite end of the connection wire is closer to the first side surface than the one end of the connection wire, when viewed in a plan view.

11. The semiconductor package of claim 10, wherein the first semiconductor chip comprises a second pad and a third pad, on a bottom surface of the first semiconductor chip facing the substrate,
the second pad is closer to the first side surface than the third pad, and
the semiconductor package further comprises:
a conductive ball on the second pad; and
a connection bump on the third pad.

12. The semiconductor package of claim 11, wherein the second semiconductor chip comprises a plurality of second semiconductor chips,
the second semiconductor chips extend parallel to a top surface of the substrate and are stacked in a stepwise arrangement, and
each of the second semiconductor chips is arranged to at least partially expose the first pad of another of the second semiconductor chips thereon.

13. The semiconductor package of claim 12, wherein the second pad comprises a plurality of second pads and the third pad comprises a plurality of third pads, and
a distance between adjacent ones of the second pads is larger than a distance between adjacent ones of the third pads.

14. The semiconductor package of claim 10, wherein at least a portion of the first pad at least partially vertically overlaps at least a portion of the substrate pad.

15. The semiconductor package of claim 11, wherein the conductive ball comprises a same material as the connection wire.

16. A method of fabricating a semiconductor package, comprising:
providing a first semiconductor chip on a carrier substrate, the first semiconductor chip comprising first pads on a top surface of the first semiconductor chip opposite the carrier substrate and connection bumps provided on at least one of the first pads;
forming conductive balls on others of the first pads;
stacking second semiconductor chips spaced apart from the first semiconductor chip on the carrier substrate to form a chip stack;
forming first connection wires connecting the conductive balls to second pads of the second semiconductor chips, the first connection wires respectively comprising a first portion connected to the conductive balls and a second portion connected to the second pads;
forming a mold layer on the carrier substrate to at least partially surround the first semiconductor chip, the chip stack, and the first connection wires;
performing a thinning process on the mold layer to remove the first portion of the first connection wires, thereby forming second connection wires, wherein the thinning process does not expose a top surface of the chip stack opposite the carrier substrate; and
forming a substrate on the mold layer and electrically connected to the second connection wires, the connection bumps, and the conductive balls.

17. The method of claim 16, wherein each of the second connection wires extends from a respective one of the second pads with an end exposed at a surface of the mold layer, and
the ends of the second connection wires are coupled to substrate pads of the substrate.

18. The method of claim 16, further comprising:
forming connection terminals on a top surface of the substrate opposite the carrier substrate; and
removing the carrier substrate.

19. The method of claim 16, wherein a distance between adjacent ones of the connection bumps is smaller than a distance between adjacent ones of the conductive balls.

20. The method of claim 16, wherein the conductive balls are formed using a capillary.
